(19) United States
(12) Patent Application Publication
(10) Pub. No.: US 2010/0044827 A1
(43) Pub. Date: Feb. 25, 2010

(54) Method for making a substrate structure comprising a film and substrate structure made by same method

(75) Inventors: Tien-Hsi Lee, Taipei (TW); Chao-Sung Lai, Taoyuan City (TW); Ching-Han Huang, Taoyuan County (TW); Chia-Che Ho, Taoyuan County (TW); Ping-Jung Wu, Taipei (TW); Shou-Jiun Jeng, Kaohsiung City (TW)

Correspondence Address: Juan Carlos A. Marquez;c/o Stites & Harbison PLLC, 1199 North Fairfax Street, Suite 900, Alexandria, VA, 22314-1437, US

(73) Assignee: Kinik Company

(21) Appl. No.: 12/230,076

(22) Filed: Aug. 22, 2008

(51) Int. Cl. H01L 29/00; H01L 21/762

(52) U.S. Cl. 257/506; 438/458; 257/E21.567; 257/E29.001

(57) ABSTRACT

A method for manufacturing a substrate structure comprising a film and a substrate structure made by this method are disclosed. The method for manufacturing a substrate structure comprising a film includes the steps of: providing a target substrate; providing an initial substrate; forming an embrittlement-layer on the initial substrate; forming a device layer on the embrittlement-layer; doping with hydrogen ions; bonding the device layer with the target substrate; and separating the device layer from the initial substrate. The hydrogen ions are added into the embrittlement-layer through doping, before an energy treatment is applied to embrittle and break the embrittlement-layer, thereby separating the device layer from the initial substrate. Since the hydrogen ions are added into the embrittlement-layer through doping, a crystal lattice structure of the device layer will not be damaged during the step of doping with hydrogen ions.

### BACKGROUND OF THE INVENTION

1. Technical Field

The present invention relates to a method for making a substrate structure comprising a film and a substrate structure made by the same method, and more particularly, to a method for making a substrate structure comprising a film using an ion doping technique and a substrate structure made by the same method.

2. Description of Related Art

U.S. Pat. No. 5,374,564 discloses a method for producing semiconductor material films. According to the method, a high dose of ions, such as gas ions of hydrogen or an inert gas, are implanted into an initial substrate to form a gas ion layer. Then, the initial substrate is bonded with a target substrate to form a single piece. A heating treatment follows, causing the gas ions in the gas ion layer to coalesce and generate numerous microbubbles. The microbubbles gradually unite into a whole and thereby partially separate the initial substrate into two layers. One of the separated layers of the initial substrate is transferred to the target substrate and thereby forms a film on the target substrate.

In the method described above, the gas ions are implanted into the initial substrate by using an ion implantation technique, which involves application of a certain amount of energy to effect gas ion bombardment on the initial substrate, thereby implanting the gas ions into the initial substrate. As a result, a crystal lattice structure of the initial substrate is likely to be damaged during gas ion implantation. In other words, a crystal lattice structure of the film transferred to the target substrate is also likely to be damaged, thereby reducing the quality. Furthermore, when the crystal lattice structure of the film is damaged, a semiconductor device subsequently formed thereon may have inferior yield.

Therefore, efforts are called for to improve the conventional ion implantation technique and thereby protect the crystal lattice structure of the film from being damaged.

### BRIEF SUMMARY OF THE INVENTION

It is an objective of the present invention to provide a method for making a substrate structure comprising a film and a substrate structure made by the same method, so that the film will not be damaged as the previous case of hydrogen ion implantation.

It is another objective of the present invention to provide a method for making a substrate structure comprising a film and a substrate structure made by the same method, wherein an embrittlement-layer can block a dopant element disposed in an initial substrate and adapted to adsorb hydrogen ions from diffusing into a device layer, and prevent the dopant element from damaging a crystal lattice structure of the device layer.

To achieve the aforementioned objectives, the present invention provides a method for making a substrate structure comprising a film, comprising steps of: providing a target substrate; providing an initial substrate containing a dopant element capable of adsorbing hydrogen ions; forming an embrittlement-layer on the initial substrate; forming a device layer on the embrittlement-layer; doping with hydrogen ions, so that the hydrogen ions are added into the embrittlement-layer; bonding the device layer with the target substrate; and separating the device layer from the initial substrate by applying an energy treatment.

To achieve the aforementioned objectives, the present invention further provides a substrate structure comprising a target substrate and a device layer bonded to the target layer.

The present invention can be implemented to provide at least the following advantageous effects:
1. An embrittlement-layer is diffused by hydrogen ions by doping the embrittlement-layer with hydrogen ions, so that a film is protected from being damaged during a hydrogen ion doping process; and
2. The use of a germanium-containing layer as an embrittlement-layer prevents a dopant element doped into an initial substrate from diffusing into a device layer and thereby protects a crystal lattice structure of a film from being damaged.

A detailed description of further features and advantages of the present invention is presented below, so that a person skilled in the art is allowed to understand and carry out the technical contents of the present invention, and can readily comprehend the objectives and advantages of the present invention by reviewing the contents disclosed herein, the appended claims and the accompanying drawings.

### BRIEF DESCRIPTION OF THE SEVERAL VIEWS OF THE DRAWINGS

The invention as well as a preferred mode of use, further objectives and advantages thereof will be understood by reference to the following detailed description of an illustrative embodiment when read in conjunction with the accompanying drawings, wherein:

FIG. 1 is a flowchart of a method for making a substrate structure comprising a film according to an embodiment of the present invention;

FIGS. 2A to 2G show different steps of the flowchart in FIG. 1, respectively;

FIG. 3A shows a target substrate having an insulating layer according to the embodiment of the present invention;

FIG. 3B shows a step of bonding a device layer with the target substrate according to the embodiment of the present invention; and

FIG. 3C shows a step of separating the device layer from an initial substrate according to the embodiment of the present invention.

### DETAILED DESCRIPTION OF THE INVENTION

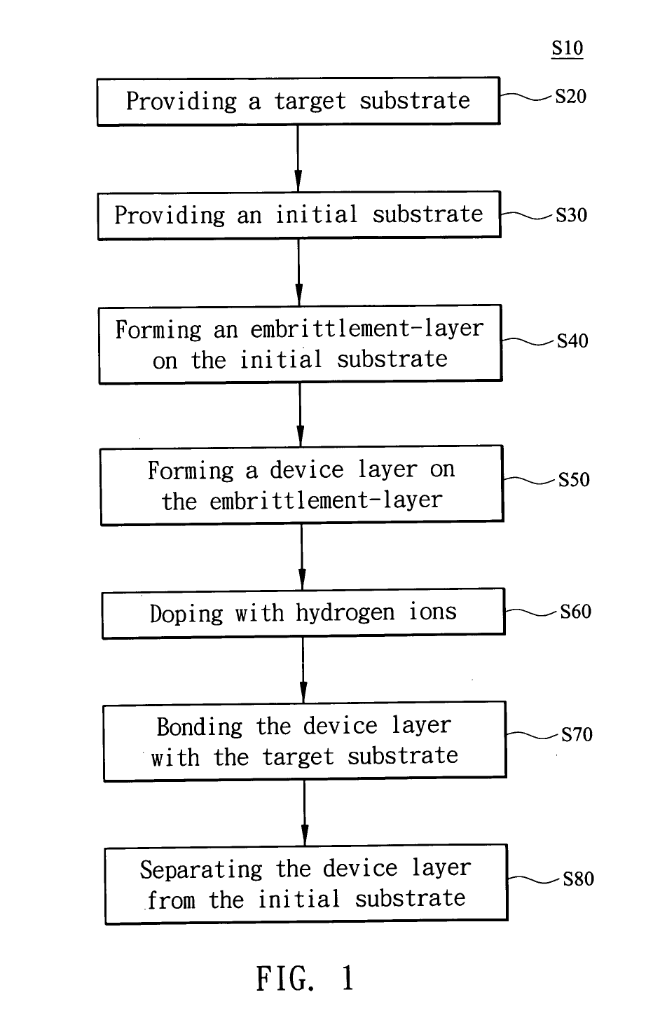

As shown in FIG. 1, a method S10 for making a substrate structure comprising a film according to an embodiment of the present invention comprises the steps of: providing a target substrate (S20); providing an initial substrate (S30); forming an embrittlement-layer on the initial substrate (S40); forming a device layer on the embrittlement-layer (S50); doping with hydrogen ions (S60); bonding the device layer with the target substrate (S70); and separating the device layer from the initial substrate (S80).

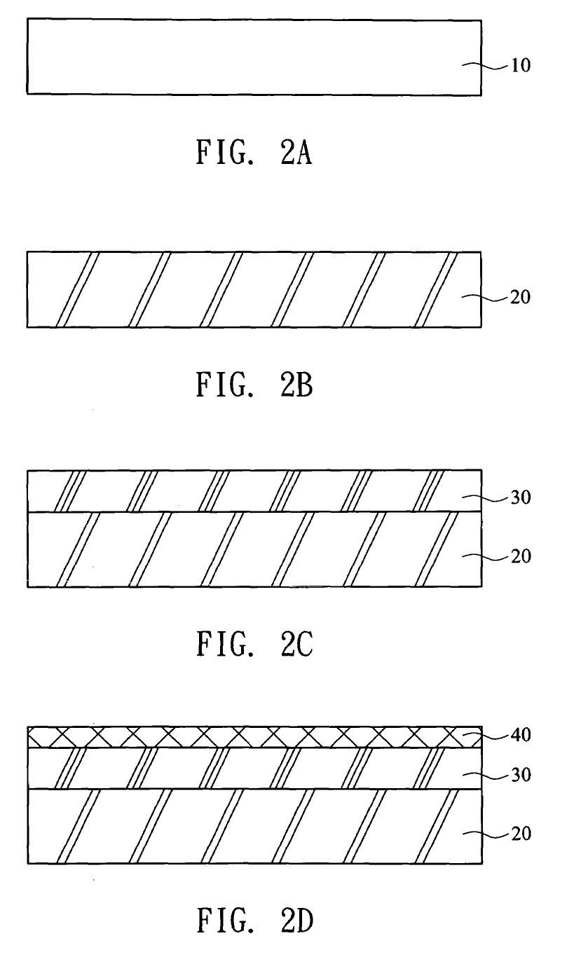

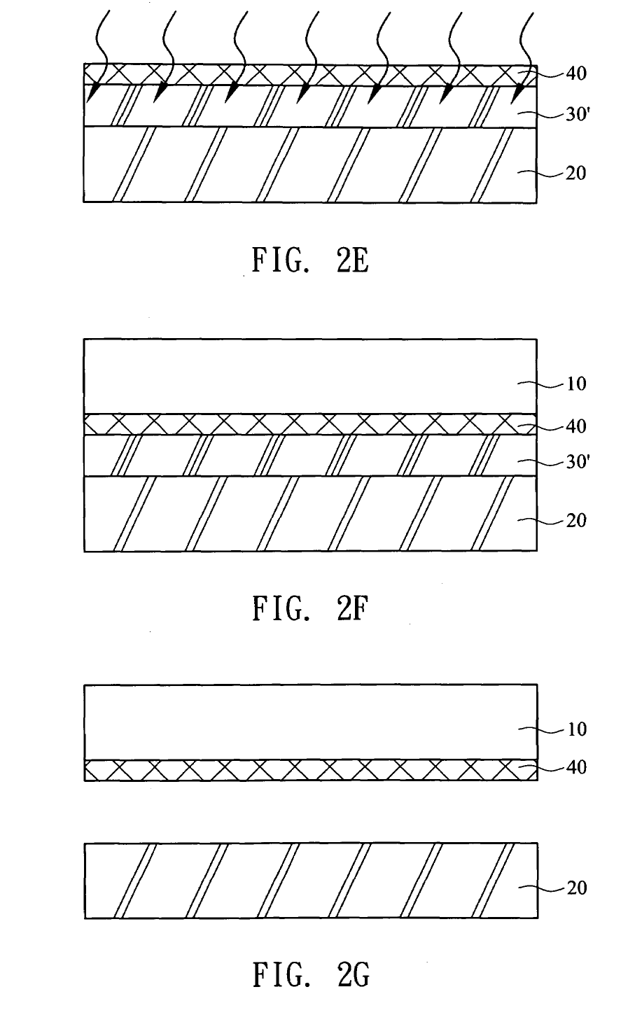

As shown in FIG. 2A and FIG. 2G, in the step of providing a target substrate (S20), a target substrate 10 is provided so that a device layer 40 can be transferred thereto. The target substrate 10 can be a silicon substrate, a sapphire substrate, a glass substrate or a quartz substrate. Alternatively, the target substrate 10 can be made of group III-V element-based materials, such as gallium arsenide (GaAs), indium phosphide (InP), gallium phosphide (GaP), aluminum nitride (AlN) or gallium nitride (GaN).

In the step of providing an initial substrate (S30), as shown in FIG. 2B, an initial substrate 20 is provided, which can be made of a group IV element-based material, so that the initial substrate 20 can be a silicon substrate, a germanium (Ge) substrate, etc. Alternatively, the initial substrate 20 can be made of group IV-IV element materials, so that the initial substrate 20 can be a silicon carbide (SiC) substrate, a silicon germanide (SiGe), etc. Or alternatively, the initial substrate 20 can made of group II-VI element-based materials, or made of group III-V element-based materials, such that the initial substrate 20 can be a gallium arsenide (GaAs) substrate, an indium phosphide (InP) substrate, a gallium phosphide (GaP) substrate, an aluminum nitride (AlN) substrate or a gallium nitride (GaN) substrate.

The initial substrate 20 is doped with a dopant element, such as atoms of boron, carbon or gallium, or a combination thereof, wherein the concentration of the dopant element is no lower than 10¹⁴/cm³. The dopant element can adsorb hydrogen ions that have diffused into the initial substrate 20 after the step of doping with hydrogen ions. For instance, if the dopant element is boron atoms, the initial substrate 20 contains boron atoms at a concentration no lower than 10¹⁴/cm³. If the initial substrate 20 is a silicon substrate and the dopant element is boron atoms, then the initial substrate 20 becomes a p-type silicon substrate, containing boron atoms at a concentration no lower than 10¹⁴/cm³.

Referring to FIG. 2C, in the step of forming an embrittlement-layer on the initial substrate (S40), an embrittlement-layer 30 is formed on the initial substrate 20 by using a chemical vapor deposition (CVD) technique, a physical vapor deposition (PVD) technique, a molecule beam epitaxy (MBE) technique, a liquid-phase epitaxy (LPE) technique or a vapor-phase epitaxy (VPE) technique. The embrittlement-layer 30 is used to absorb hydrogen ions. By applying an energy treatment, the hydrogen ions in the embrittlement-layer 30 coalesce to form gas nuclei and generate numerous microbubbles, which gradually unite into a whole and expand, thereby embrittling and breaking the embrittlement-layer 30. In addition, the embrittlement-layer 30 also blocks the dopant element in the initial substrate 20 from diffusing into the device layer 40, so that a crystal lattice structure of the device layer 40 will not be damaged.

As germanium atoms are capable of adsorbing hydrogen ions and blocking the dopant element from diffusing, the embrittlement-layer 30 can be a germanium-containing layer. For instance, the embrittlement-layer 30 can be a silicon-germanium layer having a germanium concentration ranging from 1% to 20%, or more preferably from 10% to 15%. Besides, as carbon atoms are also capable of adsorbing hydrogen ions, the embrittlement-layer 30 can also be a silicon-germanium-carbon layer having a carbon concentration ranging from 0.01% to 3%, or more preferably from 0.05% to 0.5%.

In the step of forming a device layer on the embrittlement-layer (S50), as shown in FIG. 2D, the device layer 40 can also be formed on the embrittlement-layer 30 by using the chemical vapor deposition technique, the physical vapor deposition technique, the molecule beam epitaxy technique, the liquid-phase epitaxy technique or the vapor-phase epitaxy technique. The device layer 40 can be a single-crystal film layer, such as a single-crystal silicon layer, on which a semiconductor device can be formed. Or alternatively, the device layer 40 can be a strained film layer, such as a strained silicon layer or a silicon-germanium layer, to improve features of the semiconductor device and increase stability thereof.

In the step of doping with hydrogen ions (S60), as shown in FIG. 2E, hydrogen ions are doped into the embrittlement-layer 30 from the side where the device layer 40 lies, using an ion shower technique, an ion diffusion technique or an ion implantation technique, so that the embrittlement-layer 30 becomes a embrittlement-layer 30′ which is doped with the hydrogen ions. Since the hydrogen ions are added into the embrittlement-layer 30 by using such techniques as doping and diffusion from the side where the device layer 40 is formed, the crystal lattice structure of the device layer 40 will not be damaged during the step of doping with hydrogen ions (S60).

Referring to FIG. 2F, in the step of bonding the device layer with the target substrate (S70), the device layer 40 is bonded with the target substrate 10 by using a wafer bonding technique such as a direct bonding technique, an anode bonding technique, a low-temperature bonding technique, a vacuum bonding technique, a intermediate bonding technique or a plasma-enhanced bonding technique.

In the step of separating the device layer from the initial substrate (S80), as shown in FIG. 2F and FIG. 2G, an energy treatment such as a thermal treatment, a microwave treatment or a thermal microwave treatment is applied, causing the hydrogen ions in the embrittlement-layer 30′ to coalesce and generate microbubbles, thereby embrittling and breaking the embrittlement-layer 30′, so that the device layer 40 is separated from the initial substrate 20 and transferred to the target substrate 10, and the target substrate 10 and the device layer 40 together form a substrate structure comprising a film.

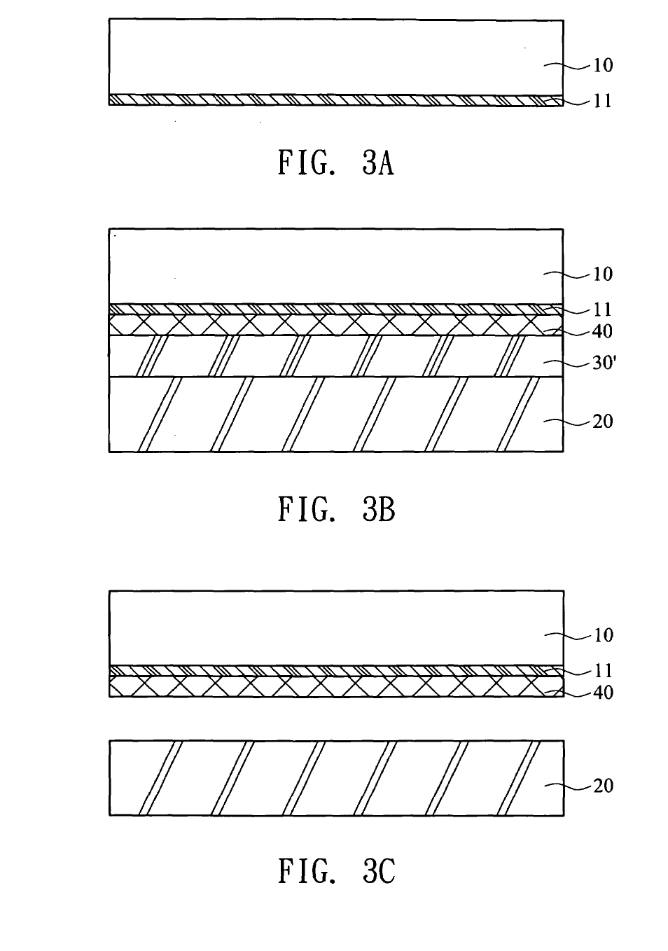

In addition, as shown in FIG. 3A, the target substrate 10 has an intended bonding surface for bonding with the device layer 40, and the intended bonding surface of the target substrate 10 can be formed with an insulating layer 11 or a plurality of insulating layers 11 formed of different materials, such as a silicon dioxide (SiO₂) layer, a silicon nitride (Si₃N₄) layer, a silicon oxynitride (SiON) layer, a silicon carbonitride (SiCN) layer, a low-k dielectric layer, a diamond layer, a diamond-like carbon layer, a silicon carbon oxyhydride (SiCOH) layer or a hafnium dioxide (HfO₂) layer.

As shown in FIG. 3B, when the target substrate 10 having the insulating layer 11 is bonded with the device layer 40 in FIG. 2E, the insulating layer 11 is interposed between the target substrate 10 and the device layer 40. As shown in FIG. 3B and FIG. 3C, by applying the energy treatment, the embrittlement-layer 30′ is broken, thereby separating the device layer 40 from the initial substrate 20 and transferring the device layer 40 to the insulating layer 11, which facilitates forming of a semiconductor device on the device layer 40.

The embodiment described above is intended to illustrate features of the present invention, so that a person skilled in the art can understand and carry out the disclosure of the present invention. The embodiment, however, is not intended to limit the scope of the present invention. Therefore, all equivalent changes or modifications which do not depart from the spirit of the present invention should be encompassed by the appended claims.

What is claimed is:

1. A method for making a substrate structure comprising a film, comprising steps of:
providing a target substrate;
providing an initial substrate containing a dopant element capable of adsorbing hydrogen ions;
forming an embrittlement-layer on the initial substrate;
forming a device layer on the embrittlement-layer;
doping with hydrogen ions, so that the hydrogen ions are added into the embrittlement-layer;
bonding the device layer with the target substrate; and
separating the device layer from the initial substrate by applying an energy treatment.

2. The method for making the substrate structure as claimed in claim 1, wherein the target substrate is one of a silicon substrate, a sapphire substrate, a glass substrate, a quartz substrate and a group III-V element-based material substrate.

3. The method for making the substrate structure as claimed in claim 1, wherein the target substrate has an intended bonding surface formed with an insulating layer, or a plurality of insulating layers.

4. The method for making the substrate structure as claimed in claim 3, wherein the insulating layer is selected from the group consisting of a silicon dioxide (SiO₂) layer, a silicon nitride (Si₃N₄) layer, a silicon oxynitride (SiON) layer, a silicon carbonitride (SiCN) layer, a low-k dielectric layer, a diamond layer, a diamond-like carbon layer, a silicon carbon oxyhydride (SiCOH) layer and a hafnium dioxide (HfO₂) layer.

5. The method for making the substrate structure as claimed in claim 1, wherein the dopant element is one of boron atoms, carbon atoms, gallium atoms and a combination thereof.

6. The method for making the substrate structure as claimed in claim 1, wherein the dopant element has a concentration no lower than 10¹⁴/cm³.

7. The method for making the substrate structure as claimed in claim 1, wherein the initial substrate is made of one of a group IV element-based material, a group IV-IV element-based material, a group III-V element-based material and a group II-VI element-based material.

8. The method for making the substrate structure as claimed in claim 7, wherein the initial substrate is one of a silicon (Si) substrate, a germanium (Ge) substrate, a silicon carbide (SiC) substrate, a silicon germanide (SiGe) substrate, a gallium arsenide (GaAs) substrate, an indium phosphide (InP) substrate, a gallium phosphide (GaP) substrate, an aluminum nitride (AlN) substrate and a gallium nitride (GaN) substrate.

9. The method for making the substrate structure as claimed in claim 1, wherein the embrittlement-layer is one of a silicon-germanium layer and a silicon-germanium-carbon layer.

10. The method for making the substrate structure as claimed in claim 9, wherein the embrittlement-layer has a germanium concentration ranging from 1% to 20% or from 10% to 15%.

11. The method for making the substrate structure as claimed in claim 9, wherein the silicon-germanium-carbon layer has a carbon concentration ranging from 0.01% to 3% or from 0.05% to 0.5%.

12. The method for making the substrate structure as claimed in claim 1, wherein the device layer is one of a single-crystal film layer and a strained film layer.

13. The method for making the substrate structure as claimed in claim 1, wherein the device layer is one of a single-crystal silicon layer, a strained silicon layer and a silicon-germanium layer.

14. The method for making the substrate structure as claimed in claim 1, wherein the step of doping with hydrogen ions is conducted by using one of an ion shower technique, an ion diffusion technique and an ion implantation technique.

15. The method for making the substrate structure as claimed in claim 1, wherein the energy treatment is one of a thermal treatment, a microwave treatment and a thermal microwave treatment.

16. A substrate structure made by the method claimed in claim 1, comprising:
a target substrate; and
a device layer bonded to the target substrate.

17. The substrate structure as claimed in claim 16, wherein the target substrate is one of a silicon substrate, a sapphire substrate, a glass substrate, a quartz substrate and a group III-V element-based material substrate.

18. The substrate structure as claimed in claim 16, wherein the target substrate has an intended bonding surface formed with an insulating layer or a plurality of insulating layers.

19. The substrate structure as claimed in claim 18, wherein the insulating layer is selected from the group consisting of a silicon dioxide (SiO₂) layer, a silicon nitride (Si₃N₄) layer, a silicon oxynitride (SiON) layer, a silicon carbonitride (SiCN) layer, a low-k dielectric layer, a diamond layer, a diamond-like carbon layer, a silicon carbon oxyhydride (SiCOH) layer and a hafnium dioxide (HfO₂) layer.

20. The substrate structure as claimed in claim 16, wherein the device layer is one of a single-crystal film layer and a strained film layer.

21. The substrate structure as claimed in claim 16, wherein the device layer is one of a single-crystal silicon layer, a strained silicon layer and a silicon-germanium layer.
